(19) United States
(12) Patent Application Publication
(10) Pub. No.: US 2005/0087834 A1
(43) Pub. Date: Apr. 28, 2005

(54) High frequency power transistor device, integrated circuit, and fabrication method thereof

(76) Inventors: Hans Norstrom, Solna (SE); Ted Johansson, Djursholm (SE)

Correspondence Address: Andreas Grubert;Baker Botts L.L.P., One Shell Plaza, 910 Louisiana, Houston, TX, 77002-4995, US

(21) Appl. No.: 10/946,870

(22) Filed: Sep. 22, 2004

(30) Foreign Application Priority Data
Oct. 24, 2003 (SE) 0302809-9

(51) Int. Cl. H01L 29/00

(52) U.S. Cl. 257/508

(57) ABSTRACT

A monolithically integrated high frequency lateral power transistor device comprises a semiconductor substrate (10; 40), a gate region (17; 41-43) including a gate semiconductor layer region (18, 42) on top of a gate insulation layer region (19, 41), source (16) and drain (15) regions, and a channel region arranged beneath the gate region, wherein the channel region interconnects the source and drain regions. An oxide region (21; 45) is provided on top of the gate region, wherein the oxide region overlaps the gate region and has a substantially planar upper surface (21a). A Faraday shield is provided as a conductive layer (22; 46) on top of the oxide region, wherein the conductive layer covers an edge (17a) of the gate region as seen from above, and leaves a portion (15a) of the drain region uncovered as seen from above.

### PRIORITY

This application claims priority to Swedish application No. 0302809-9 filed Oct. 24, 2003.

### TECHNICAL FIELD OF THE INVENTION

The present invention generally relates to the field of integrated circuit technology, and more specifically the invention relates to a high frequency power transistor device, to an integrated circuit including the power transistor device, and to a fabrication method of the integrated circuit, respectively.

### DESCRIPTION OF RELATED ART AND BACKGROUND OF THE INVENTION

In order to reduce the gate-to-drain capacitance in LDMOS RF power transistors a Faraday shield is commonly provided above the gate structure. A structure of this kind, which has been widely used for many years, is described in A. Wood, C. Dragon, W. Burger, “High performance silicon LDMOS technology for 2 GHz RF Power Amplifier Applications, IEDM Tech. Dig. 1996, p. 87. The Faraday shield is provided above the gate as a metal layer on top of a conformally deposited oxide, see FIG. 1 of the article above.

Different variations of the design and fabrication of such structures are disclosed in U.S. Pat. Nos. 5,119,149; 5,252,848; 6,001,710; 6,215,152; and 6,222,229.

### SUMMARY OF THE INVENTION

The layout of the structure described by Wood et al. needs a thick, conformal oxide with good step coverage to obtain a large shield-source distance in order not to increase the gate-source capacitance, while still keeping a reasonable shield-drain distance. Further, the Faraday shield is effective only on the drain side of the gate, and may therefore cover unnecessary large portions of the structure. Still further, since the purpose of the shield layer is only to provide a ground plane, it is not necessary to use a thick metal layer for this purpose only.

Accordingly, it is an object of the present invention to provide a monolithically integrated high frequency lateral power transistor device with a Faraday shield above a gate region thereof, which overcomes the limitations associated with the prior art device described above.

Further, it is an object of the invention to provide an integrated circuit comprising such a lateral power transistor device.

Still further, it is an object of the invention to provide a method in the fabrication of an integrated circuit, particularly an integrated circuit for radio frequency applications, which includes a lateral power transistor device that accomplishes the above object.

These objects can according to the present invention be attained by a monolithically integrated high frequency lateral power transistor device comprising a semiconductor substrate, a gate region including a gate semiconductor layer region on top of a gate insulation layer region, source and drain regions, a channel region arranged beneath the gate region, the channel region interconnecting the source and drain regions, and a Faraday shield above the gate region, an oxide region on top of the gate region, the oxide region overlapping the gate region and comprising a substantially planar upper surface; and wherein the Faraday shield is provided as a conductive layer on top of the oxide region, the conductive layer covering an edge of the gate region as seen from above, and leaving a portion of the drain region uncovered as seen from above.

The power transistor device can be an LDMOS device. The oxide region can be made of a thick oxide. The upper surface of the oxide region can be chemically mechanically polished or planarized using masking and dry back-etching. The edge of the gate region can be neighboring the drain region. The conductive layer may comprise a transition metal, particularly titanium. The conductive layer can be galvanically connected to the source region. The conductive layer may comprise at least one metal film resistor formed therein. The power transistor may be part of an integrated circuit.

The object can also be achieved by a method in the fabrication of an integrated circuit, particularly an integrated circuit for radio frequency applications, including a lateral power transistor device, comprising the steps of:
providing a semiconductor substrate,
forming source and drain regions in the substrate,
forming a channel region in the substrate between the source and drain regions, and
forming a gate region on the substrate, the gate region including a gate semiconductor layer region on top of a gate insulation layer region,
depositing an oxide on top of the source, drain and gate regions,
chemically mechanically polishing the oxide to obtain a substantially planar upper surface,
patterning and etching the oxide to expose portions of the source and drain regions, and
forming a Faraday shield as a first conductive layer region on top of the patterned and etched oxide, the first conductive layer region covering an edge of the gate region as seen from above, and leaving a portion of the drain region uncovered as seen from above.

The oxide can be formed as a thick oxide. The edge of the gate region can be neighboring the drain region. The first conductive layer can be formed using a transition metal, preferably titanium. Second and third conductive layer regions can be formed simultaneously with the formation of the first conductive layer region, wherein the second conductive layer region being formed on top of the exposed portion of the source region and the third conductive layer region being formed on top of the exposed portion of the drain region. The first conductive layer region can be galvanically connected to the second conductive layer region. At least one metal film resistor structure can be formed simultaneously with the formation of the first conductive layer region.

By means of providing an oxide region on top of the gate region of the power transistor device, where the oxide region overlaps the gate region and has a substantially planar upper surface, the Faraday shield can be provided as a substantially planar conductive layer on top of the oxide region, where the conductive layer covers an edge of the region a, and leaves a portion of the transistor drain region uncovered.

No particular requirements are put on the formation of the oxide region. By deposition a thick oxide with no requirements on conformity, the use of e.g. CMP (chemical mechanical polishing) creates an oxide layer region with a planar upper surface above the gate edge on the drain side of the transistor, thus simplifying the conductive layer shield formation. The shield metal consists preferably of a thin deposited bi-layer of Ti/TiN, which can also be used as contact layer regions for the source and drain areas. However, other transition metals for the shield may be used.

The design of the shield metal is advantageously such that only a few narrow metal strips connect the shield to the source contact region. In this manner, the shield- or ground-to-source capacitance is lowered.

Alternatively, the conductive layer shield is connected to another electric potential or is left electrically unconnected.

Further, the conductive layer used for the shield and for the source and drain contact layer regions can be used for the formation of metal film resistors on top of the oxide layer region. Investigations have shown that a sheet resistivity value of about 14 Ohms/square is feasible, which is in between the 1-5 Ohms/square offered by a silicided gate material, and the 50-5000 Ohms/square offered by the conventional BiCMOS polycrystalline silicon resistors.

Further characteristics of the invention and advantages thereof will be evident from the detailed description of the preferred embodiments of the present invention given hereinafter and the accompanying FIGS. 1-4, which are given by way of illustration only, and thus are not limitative of the present invention.

### BRIEF DESCRIPTION OF THE DRAWINGS

FIG. 1 is a highly enlarged schematic cross-sectional view of an LDMOS power transistor device according to a preferred embodiment of the present invention.

FIGS. 2a-b show layouts of some important masks for the manufacturing of an inventive LDMOS power transistor device.

FIGS. 3a-g are highly enlarged schematic cross-sectional views of a portion of a semiconductor structure during processing according to a preferred embodiment of the present invention.

FIG. 3h is a highly enlarged perspective view of the semiconductor structure portion as shown in the cross-sectional view in FIG. 3f.

FIGS. 4a and c are each a highly enlarged schematic cross-sectional view of a portion of a semiconductor structure during processing according to a further preferred embodiment of the present invention.

FIG. 4b is a top view of a metal film resistor comprised in the semiconductor structure of FIG. 4a.

### DETAILED DESCRIPTION OF EMBODIMENTS

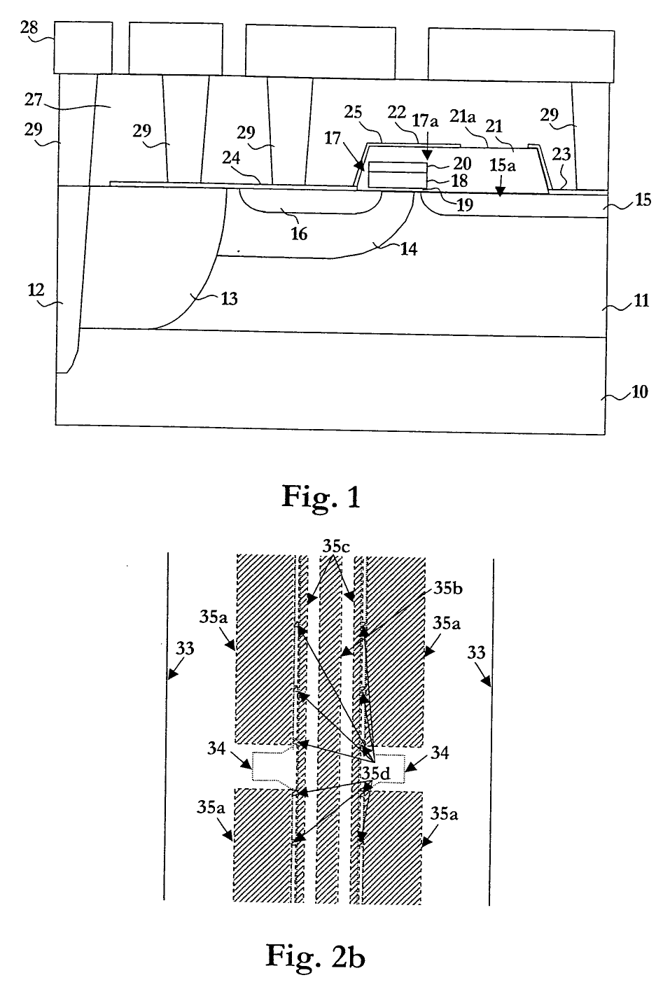

An LDMOS transistor device according to a preferred embodiment of the present invention is shown in FIG. 1 in an enlarged cross-sectional view. The LDMOS transistor device, which is particularly adapted for high power radio frequency applications, comprises a P+ type doped semiconductor substrate 10, on which a P− type doped epitaxial layer 11 is formed.

A metal filled trench 12, a P+ type doped sinker region 13, a P type doped well 14, and an N type doped drain region 15 are formed in the epitaxial layer 11. An N type doped source 16 is formed in the P type doped well 14.

Further, a gate region 17 is provided, which includes a semiconductor layer region 18 on top of a gate insulation layer region 19. A layer region 20 of lower resistivity, e.g. TiSi₂ or other silicide material, is formed on top of the gate semiconductor layer region 18.

According to the present invention a Faraday shield is formed above the gate region. To this end an oxide region 21 is provided on top of the gate region 17, where the oxide region 21 overlaps the gate region 17 completely, i.e. the oxide region 21 encapsulates the gate region 17. Preferably, the oxide region 21 extends a certain distance into the area above the N type doped drain region 15 as illustrated.

The oxide region 21 has a substantially planar upper surface 21a. Preferably, the upper surface 21a is polished, e.g. by use of a chemical mechanical polishing (CMP) technique. Alternatively, the upper surface 21a is planarized using masking and dry back-etching. References to CMP and dry back-etching can be found in J. D. Plummer, M. D. Deal, and P. B. Griffin, “Silicon VLSI Technology”, Prentice-Hall 2000, pp. 710-715, the content of which being hereby incorporated by reference. The oxide region is made of a thick oxide. Preferably, the oxide thickness is about 500-2000 Å on top of the gate region 17 and about 4000-8000 Å elsewhere. In a typical example, the oxide thickness can be about 1500 Å on top of the gate region 17 and about 6000 Å elsewhere.

The Faraday shield is provided as a thin conductive layer 22 on top of the oxide region 21, where the conductive layer 22 covers, as seen from above, an edge 17a of the gate region 17, which faces the drain region 15, and where the conductive layer 22 leaves a portion 15a of the drain region 15 uncovered as seen from above. The thin conductive layer 22 may consist of titanium or other transition metal, and may have thickness of between about 500 Å and about 2000 Å.

The use of a planar oxide layer region 21 on top of the gate region 17 simplifies considerably the formation of the Faraday shield.

In one embodiment, the conductive layer regions for electrical connection of the drain and source regions 15, 16 are provided in the very same conductive layer as is used for the Faraday shield. Preferably, these contact layer regions 23, 24 are silicided in a heat treatment.

The Faraday shield 22 may be connected to any given electric potential, or it may be left freely floating without being connected at all. However, in the preferred embodiment the Faraday shield 22 is connected to the source region 16 via a few narrow metal strips, of which one is shown as a detail 25 in FIG. 1. The source region 16 is in turn connected to ground.

In FIG. 1 a passivation layer 27, a first metal layer 28, and electrical connections 29 between the active components and the first metal layer 28 are shown. Thus, the Faraday shield layer 22 is not part of the metallization of the transistor device, wherein about 0.8-1.5 micron thick metallic layers are provided and connected to active regions by means of via plugs filled with conductive material. The Faraday shield layer 22 is provided as a thin conductive layer below the metallization layers of the transistor device.

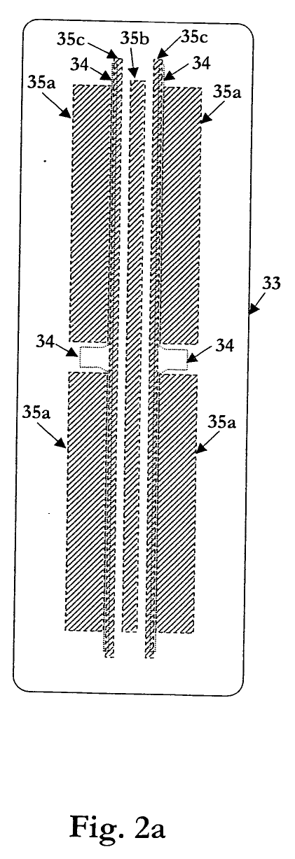

In FIGS. 2a-b layouts of some important masks for the manufacturing of an LDMOS power transistor device of the present invention are illustrated. In FIG. 2a the complete masks are shown, whereas in FIG. 2b the central portions of the masks are shown highly enlarged.

In FIGS. 2a-b reference numeral 33 denotes the mask for the active region of the transistor device, i.e. where no field oxide shall be formed, 34 denotes the mask for the gate region, and 35a-d denotes the mask for the conductive shield and source/drain layer (the mask detail 35d is only visible in FIG. 2b).

The example LDMOS transistor as illustrated in FIGS. 2a-b has two gate regions and two source regions arranged symmetrically on each sides of a centrally arranged drain region. The mask 35a-d illustrates the covered areas during etching of the conductive titanium layer. Here, 35a denotes the areas for the conductive titanium layer region connected to the source regions, 35b denotes the area for the conductive titanium layer region connected to the drain region, 35c denotes the area for the conductive titanium Faraday shield layer region above the edges of the gate regions facing the drain region, and 35d denotes the area for the conductive titanium layer region interconnecting the conductive titanium Faraday shield layer region with the source regions.

It shall be appreciated that while the illustrated preferred embodiment of the LDMOS transistor is an NMOS device, the present invention is not limited in this respect. The invention is equally applicable to PMOS devices.

It shall further be appreciated that while the present invention is primarily intended for radio frequency power silicon LDMOS devices, it may as well be useful for smaller devices in silicon-based integrated radio frequency circuits. Further, the transistor device of the present invention may be realized in other materials such as e.g. SiC, GaAs, etc. if the gate insulator layers are modified accordingly.

Below, a preferred embodiment of manufacturing a monolithically integrated LDMOS transistor device of the present invention is described. Many of the process steps, e.g. including ion implanting steps for forming wells and source and drain regions, are well known to the person skilled in the art and these steps will therefore not be described at all here, or will only be schematically indicated. The main focus is put on how the Faraday shield is formed.

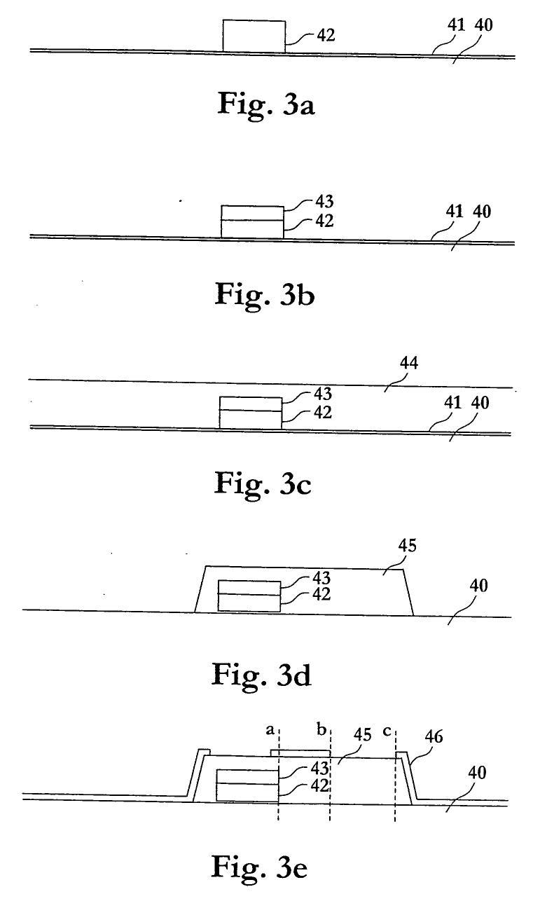

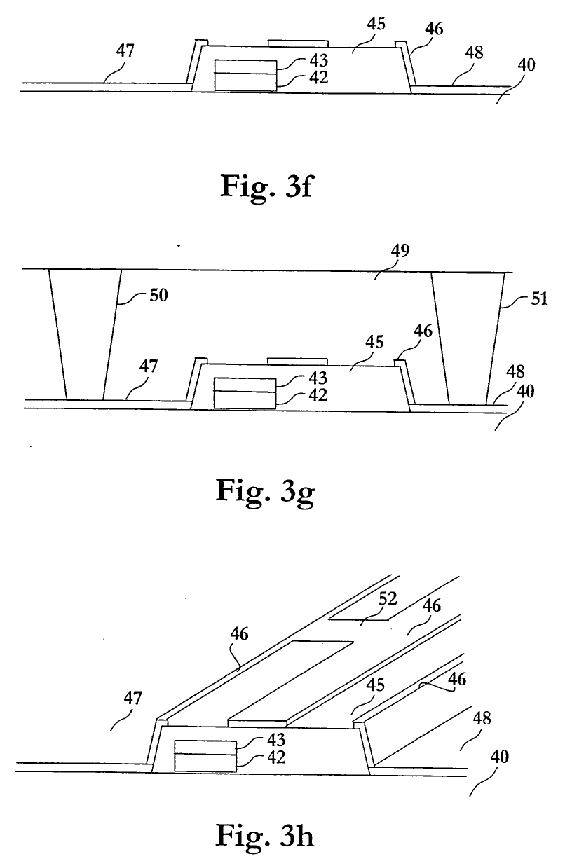

In FIG. 3a a semiconductor structure is shown, which includes a partially processed LDMOS transistor. Reference numeral 40 denotes a silicon substrate, 41 denotes a gate oxide layer region, and 42 denotes a polycrystalline silicon gate layer region. The polycrystalline silicon gate 42 is N type doped and its length may be about 0.5 μm.

In FIG. 3b titanium disilicide (TiSi₂) or other silicide 43 is shown as being formed on top of the gate 42. This formation can be made in a self-aligned manner using a structure known as polycide. Instead, in this example, the thin oxide has been formed on top and on the sides of the gate 42. Masking and etching are performed to remove oxide on top of the gate 42, titanium or other conductive material is deposited on the wafer, and using a short heat treatment, silicide is formed on the exposed top of the gate 42. Remaining unreacted titanium is removed by wet cleaning.

On top of the gate 42 and the silicide 43, a thick oxide layer 44, e.g. 8000-1000 Å thick, is deposited and subsequently planarized using chemical mechanical polishing (CMP). The resulting structure is illustrated in FIG. 3c.

Thereafter, the oxide layer 44 is removed on source and drain areas by masking and dry etching. The remaining oxide layer region is denoted 45 in FIG. 3d. Note that the drain contact is located to the right of the oxide layer region and that there is a longer distance to this contact, which is in contrary to a conventional MOS structure.

Next, as shown in FIG. 3e, a shield layer 46 is deposited, patterned, and etched. It may consist of a bi-layer of Ti/TiN with a thickness of about 300 Å/500 Å. Alternatively, the shield layer is formed of other conductive material to another thickness.

The layout of the shield layer is selected so that the shield layer 46 covers, as seen from above, an edge of the gate as illustrated by the dashed line a, and so that the shield layer 46 leaves a portion of the drain region 15 uncovered as seen from above. This portion is located between the dashed lines b and c.

A heat treatment may follow to form silicide on those areas, where the titanium layer is in contact with exposed silicon areas, i.e. at source and drain areas. In FIG. 3f the silicided source contact layer is denoted 47 and the silicided drain contact layer is denoted 48.

Alternatively, the formation of the shield layer 46 and the formation of the silicided source and drain contact layers 47, 48 are performed in two separate steps. Firstly, titanium or other conductive material is deposited on source and drain areas, and is made to form a silicide, after which remaining conductive material that has not reacted with the silicon is removed by wet cleaning. Secondly, conductive material, e.g. a bi-layer of Ti/TiN, is deposited and etched to form the shield layer 46. This two-step method can be performed without the use of any further masks since the bi-layer of Ti/TiN may be formed on top of the silicided source and drain contact areas.

Finally, back-end processing is performed with conventional deposition of a thick passivation layer 49, contacts 50, 51 down to source and drain contact layers 47, 48, and multi-layer metallization (not illustrated). The structure before deposition of the first metal layer is schematically illustrated in FIG. 3g.

In FIG. 3h the structure of FIG. 3f is shown in a perspective view. Here it is clearly illustrated that the shield layer 46 can be connected to the silicided source contact layer 47 by means of a narrow metal strip 52.

Further, the conductive shield layer of the present invention, consisting of a metal such as Ti/TiN bi-layer, may be used to form a metal film resistor with advantageous electrical and thermal properties. Two different manners of connecting such a metal film resistor are available.

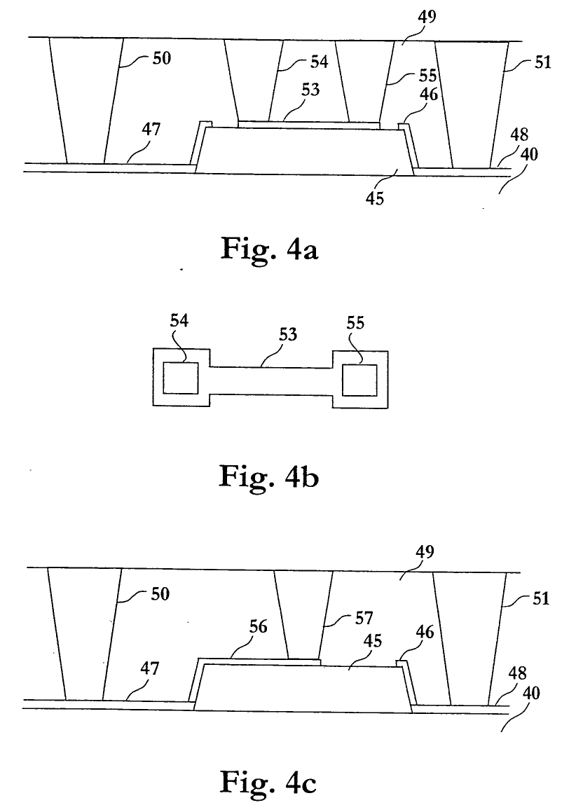

In FIG. 4a a semiconductor structure is shown, which includes a metal film resistor 53 made in the conductive shield layer, the resistor 53 being not connected to the source contact region 47, but is patterned as a discrete resistor on top of the oxide isolation 45. The resistor 53 is connected to the multi-layer metallization by two contacts 54, 55 similar to how the gate, source and drain regions are contacted. Note that the resistor is preferably not located above the gate structure of the transistor as illustrated in FIG. 1, but laterally separated from there. A typical resistor layout of the metal film resistor 53 with the two contacts 54, 55 is shown in FIG. 4b.

In FIG. 4c a semiconductor structure is shown, which includes a metal film resistor 56 made in the conductive shield layer, the resistor 56 being connected to the source contact region 47 and thus to ground. The resistor 56 is connected to the multi-layer metallization by one resistor contact 57 and the source contact 50. Direct connection to ground may be needed in the circuit design, for instance for a damping resistor in series with a matching inductor to reduce the Q-value and increase the bandwidth.

A deposited Ti/TiN stack with layer thicknesses in the order of 300 Å and 500 Å gave a measured resistance value of about 14 Ohms/square, which is in between the 1-5 Ohms/square offered by a silicided gate material, and the 50-5000 Ohms/square offered by the conventional BiCMOS polycrystalline silicon resistors. This indicates that very attractive resistance values can be obtained by suitable design, e.g. for integrated trimming resistors in LDMOS circuits.

The temperature dependence of the inventive shield layer film resistors is lower than that of the polycrystalline silicon gate layer resistors. In RF power devices, which by nature are operated at high temperatures and at high frequencies, where temperature effects and parasitics have an important role for the performance and stability of the circuits, the inventive shield layer film resistor is particularly advantageous.

It shall be understood that the inventive shield layer film resistors may be provided in the conductive shield layer at any suitable lateral location of an integrated circuit, e.g. on top of the transistor device described in the present text, above other devices or components of the circuit, or above field insulation regions.

1. A monolithically integrated high frequency lateral power transistor device comprising:
a semiconductor substrate,
a gate region including a gate semiconductor layer region on top of a gate insulation layer region,
source and drain regions,
a channel region arranged beneath said gate region, said channel region interconnecting said source and drain regions, and
a Faraday shield above said gate region,
an oxide region on top of said gate region, said oxide region overlapping said gate region and comprising a substantially planar upper surface; and wherein
said Faraday shield is provided as a conductive layer on top of said oxide region, said conductive layer covering an edge of said gate region as seen from above, and leaving a portion of said drain region uncovered as seen from above.

2. The power transistor device of claim 1, wherein said power transistor device is an LDMOS device.

3. The power transistor device of claim 1, wherein said oxide region is made of a thick oxide.

4. The power transistor device of claim 1, wherein the upper surface of said oxide region is chemically mechanically polished or planarized using masking and dry back-etching.

5. The power transistor device of claim 1, wherein said edge of the gate region is neighboring said drain region.

6. The power transistor device of claim 1, wherein said conductive layer comprises a transition metal, particularly titanium.

7. The power transistor device of claim 1, wherein said conductive layer is galvanically connected to said source region.

8. The power transistor device of claim 1, wherein said conductive layer comprises at least one metal film resistor formed therein.

9. An integrated circuit comprising the power transistor device of claim 1.

10. A method in the fabrication of an integrated circuit, particularly an integrated circuit for radio frequency applications, including a lateral power transistor device, comprising the steps of:
providing a semiconductor substrate,
forming source and drain regions in said substrate,
forming a channel region in said substrate between said source and drain regions, and
forming a gate region on said substrate, said gate region including a gate semiconductor layer region on top of a gate insulation layer region,
depositing an oxide on top of said source, drain and gate regions,
chemically mechanically polishing said oxide to obtain a substantially planar upper surface,
patterning and etching said oxide to expose portions of said source and drain regions, and
forming a Faraday shield as a first conductive layer region on top of said patterned and etched oxide, said first conductive layer region covering an edge of said gate region as seen from above, and leaving a portion of said drain region uncovered as seen from above.

11. The method of claim 10, wherein said oxide is formed as a thick oxide.

12. The method of claim 10, wherein said edge of said gate region is neighboring said drain region.

13. The method of claim 10, wherein said first conductive layer is formed using a transition metal, preferably titanium.

14. The method of claim 10, wherein second and third conductive layer regions are formed simultaneously with the formation of said first conductive layer region, said second conductive layer region being formed on top of said exposed portion of said source region and said third conductive layer region being formed on top of said exposed portion of said drain region.

15. The method of claim 14, wherein said first conductive layer region is galvanically connected to said second conductive layer region.

16. The method of claim 10, wherein at least one metal film resistor structure is formed simultaneously with the formation of said first conductive layer region.
